(19) United States
(12) Patent Application Publication
(10) Pub. No.: US 2005/0056921 A1
(43) Pub. Date: Mar. 17, 2005

(54) Stacked module systems and methods

(75) Inventors: James Douglas Wehrly JR., Austin, TX (US); James W. Cady, Austin, TX (US); Julian Partridge, Austin, TX (US); David L. Roper, Austin, TX (US)

Correspondence Address: J. Scott Denko;Andrews & Kurth, L.L.P., Suite 1700, 111 Congress Ave., Austin, TX, 78701, US

(73) Assignee: Staktek Group L.P.

(21) Appl. No.: 10/845,029

(22) Filed: May 13, 2004

Related U.S. Application Data
(63) Continuation-in-part of application No. PCT/US03/29000, filed on Sep. 15, 2003.

(51) Int. Cl. H01L 23/02

(52) U.S. Cl. 257/686

(57) ABSTRACT

The present invention stacks chip scale-packaged integrated circuits (CSPs) into modules that conserve PWB or other board surface area. The CSPs employed in stacked modules devised in accordance with the present invention are connected with flex circuitry. That flex circuitry may exhibit one or more conductive layers with preferred embodiments having two conductive layers. A form standard is disposed along the lower planar surface and extends laterally beyond the package of one or more CSPs in a stacked module. The form standard provides a physical form that allows many of the varying package sizes found in the broad family of CSP packages to be used to advantage while employing a standard connective flex circuitry design. In a preferred embodiment, the form standard will be comprised of heat conductive material such as copper, for example.

### BACKGROUND OF THE INVENTION

A variety of techniques are used to stack packaged integrated circuits. Some methods require special packages, while other techniques stack conventional packages.

The predominant package configuration employed during the past decade has encapsulated an integrated circuit (IC) in a plastic surround typically having a rectangular configuration. The enveloped integrated circuit is connected to the application environment through leads emergent from the edge periphery of the plastic encapsulation. Such “leaded packages” have been the constituent elements most commonly employed by techniques for stacking packaged integrated circuits.

Leaded packages play an important role in electronics, but efforts to miniaturize electronic components and assemblies have driven development of technologies that preserve circuit board surface area. Because leaded packages have leads emergent from peripheral sides of the package, leaded packages occupy more than a minimal amount of circuit board surface area. Consequently, alternatives to leaded packages known as chip scale packaging or “CSP” have recently gained market share.

CSP refers generally to packages that provide connection to an integrated circuit through a set of contacts (often embodied as “bumps” or “balls”) arrayed across a major surface of the package. Instead of leads emergent from a peripheral side of the package, contacts are placed on a major surface and typically emerge from the planar bottom surface of the package. The absence of “leads” on package sides renders most stacking techniques devised for leaded packages inapplicable for CSP stacking.

A variety of previous techniques for stacking CSPs typically present complex structural arrangements and thermal or high frequency performance issues. For example, thermal performance is a characteristic of importance in CSP stacks. Further, many stacking techniques result in modules that exhibit profiles taller than may be preferred for particular applications.

What is needed, therefore, is a technique and system for stacking CSPs that provides a thermally efficient, reliable structure that performs well at higher frequencies but does not add excessive height to the stack yet allows production at reasonable cost with readily understood and managed materials and methods.

### SUMMARY OF THE INVENTION

The present invention stacks chip scale-packaged integrated circuits (CSPs) into modules that conserve PWB or other board surface area. Although the present invention is applied most frequently to chip scale packages that contain one die, it may be employed with chip scale packages that include more than one integrated circuit die.

Multiple numbers of CSPs may be stacked in accordance with the present invention. The CSPs employed in stacked modules devised in accordance with the present invention are connected with flex circuitry. That flex circuitry may exhibit one or two or more conductive layers with preferred embodiments having two conductive layers.

A form standard is disposed along the planar surface of one or more CSPs in a stacked module. Preferably, the form standard is disposed along the lower planar surface and extends laterally beyond the package of the CSP with which it is associated. The form standard can take many configurations and may be used where flex circuits are used to connect CSPs to one another in stacked modules. The form standard provides a physical form that allows many of the varying package sizes found in the broad family of CSP packages to be used to advantage while employing a standard connective flex circuitry design. In a preferred embodiment, the form standard will be devised of heat transference material, a metal such as copper, for example, would be preferred.

### SUMMARY OF THE DRAWINGS

FIG. 1 is an elevation view of a high-density circuit module devised in accordance with a preferred embodiment of the present invention.

FIG. 2 is an elevation view of a four-level module devised in accordance with a preferred embodiment of the present invention.

FIG. 3 is an enlarged depiction of the area marked “A” in FIG. 2.

FIG. 4 is a view of a form standard employed in a preferred embodiment of the present invention.

FIG. 5 is a plan view with partial cutaway from below of a preferred embodiment of the present invention.

FIG. 6 is a plan view from below of a preferred embodiment of the present invention.

FIG. 7 is a perspective depiction of a preferred embodiment of the present invention.

FIG. 8 depicts a unit that may be employed in preferred embodiments of the present invention.

FIG. 9 depicts a sectional view of a connective area and a layered construction for a preferred flex circuitry employed in a preferred embodiment of the present invention.

FIG. 10 depicts a sectional view of a connective area and layered construction for an alternative preferred flex circuitry employed in a preferred embodiment of the present invention.

### DESCRIPTION OF PREFERRED EMBODIMENTS

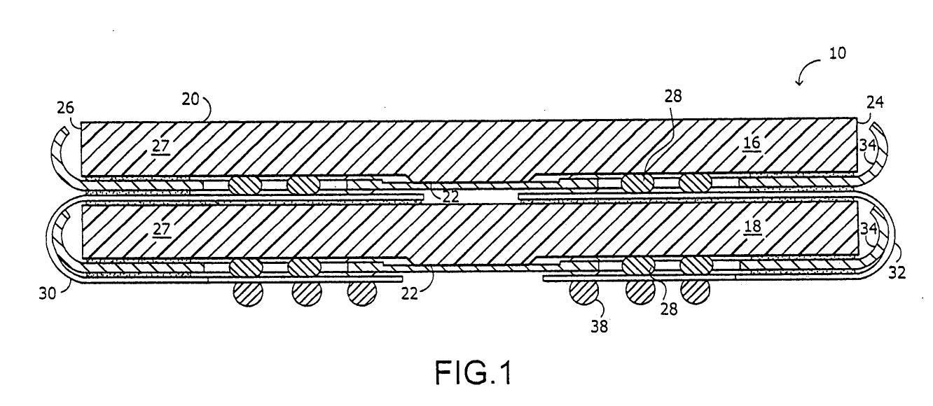

FIG. 1 is an elevation view of module 10 devised in accordance with a preferred embodiment of the present invention. In this embodiment, module 10 includes upper CSP 16 and lower CSP 18. Each of the constituent CSPs has an upper surface 20 and a lower surface 22 and opposite lateral edges 24 and 26 and includes at least one integrated circuit typically surrounded by a plastic body 27. The body need not be plastic, but a large majority of packages in CSP technologies are plastic. Those of skill will realize that the present invention may be devised to create modules with different size CSPs and that the constituent CSPs may be of different types within the same module 10. For example, one of the constituent CSPs may be a typical CSP having lateral edges 24 and 26 that have an appreciable height to present a “side” while other constituent CSPs of the same module 10 may be devised in packages that have lateral edges 24 and 26 that are more in the character of an edge rather than a side having appreciable height.

The invention is used with CSP packages of a variety of types and configurations such as, for example, those that are die-sized, as well those that are near chip-scale as well as the variety of ball grid array packages known in the art. It may also be used with those CSP-like packages that exhibit bare die connectives on one major surface. Thus, the term CSP should be broadly considered in the context of this application. Collectively, these will be known herein as chip scale packaged integrated circuits (CSPs) and preferred embodiments will be described in terms of CSPs, but the particular configurations used in the explanatory figures are not, however, to be construed as limiting. For example, the elevation view of FIG. 1 depicts a CSP of a particular profile known to those in the art, but it should be understood that the figures are exemplary only. The invention may be employed to advantage in the wide range of CSP configurations available in the art where an array of connective elements is available from at least one major surface. The invention is advantageously employed with CSPs that contain memory circuits, but may be employed to advantage with logic and computing circuits where added capacity without commensurate PWB or other board surface area consumption is desired.

Typical CSPs, such as, for example, ball-grid-array (“BGA”), micro-ball-grid array, and fine-pitch ball grid array (“FBGA”) packages have an array of connective contacts embodied, for example, as leads, bumps, solder balls, or balls that extend from lower surface 22 of a plastic casing in any of several patterns and pitches. An external portion of the connective contacts is often finished with a ball of solder. Shown in FIG. 1 are contacts 28 along lower surfaces 22 of the illustrated constituent CSPs 16 and 18. Contacts 28 provide connection to the integrated circuit or circuits within the respective packages. The depicted contacts 28 have been compressed prior to the complete construction of module 10.

However, those of skill should understand that although contacts 28 as depicted in FIG. 1 are preferably compressed prior to construction of module 10, contacts 28 of CSPs employed in embodiments of the invention need not be necessarily compressed or reduced in their height above the planar surface above which such contacts typically rise.

Flex circuits 30 and 32 are shown connecting the constituent CSPs of the module of FIG. 1. The entire flex circuit may be flexible or, as those of skill in the art will recognize, a PCB structure made flexible in certain areas to allow conformability around CSPs and rigid in other areas for planarity along CSP surfaces may be employed as an alternative flex circuit in the present invention. For example, structures known as rigid-flex may be employed. More than one flex circuit may be employed to implement the connections between constituent CSPs in a module 10.

As shown in FIG. 1, a form standard 34 is disposed along lower planar surface 22 and laterally beyond edges 26 and 24 of body 27 of CSPs 16 and 18 in stacked module 10. Form standard 34 is disposed along a surface of a CSP even if literally separated from that surface by adhesive, for example. Form standard 34 may take many configurations, with examples of embodiments having a downward opening form standard shown in pending U.S. patent application Ser. No. 10/453,398, filed Jun. 3, 2003, commonly owned by the assignee of the present invention, which is incorporated by reference. In some cases, embodiments that employ downward opening form standards that are disposed across the upper surface of and arc underneath the lower surface of the CSP with which the form standard is associated may exhibit higher profiles. Module 10 exhibits module contacts 38 through which module 10 connects to application environments in a preferred embodiment. Those of skill will recognize that module contacts 38 are not required to connect module 10 to an application environment and other connective strategies may be employed such as, for example, direct pad to pad connection schemes.

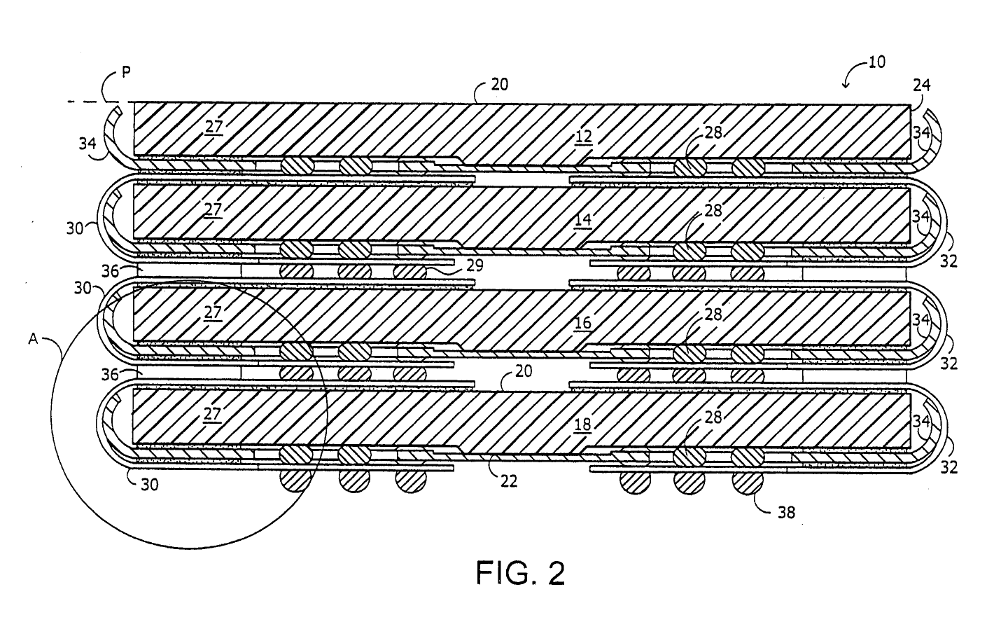

FIG. 2 depicts a four-level high embodiment of module 10 that employs four form standards 34 with a form standard 34 associated with each of CSPs 12, 14, 16 and 18. Those of skill will recognize that each level in module 10 need not have a form standard but where maximum heat extraction is desired, use of multiple form standards 34 is preferred. FIG. 2 depicts an imaginary plane “P” defined by upper surface 20 of CSP 12. Those of skill will note that in the depicted embodiment of FIG. 2, the form standard 34 is associated with CSP 12 does not extend above plane P just as for each CSP of the embodiment, the respective form standard does not rise above its respective plane P. This is not required but is an adjunct in keeping a low profile for module 10.

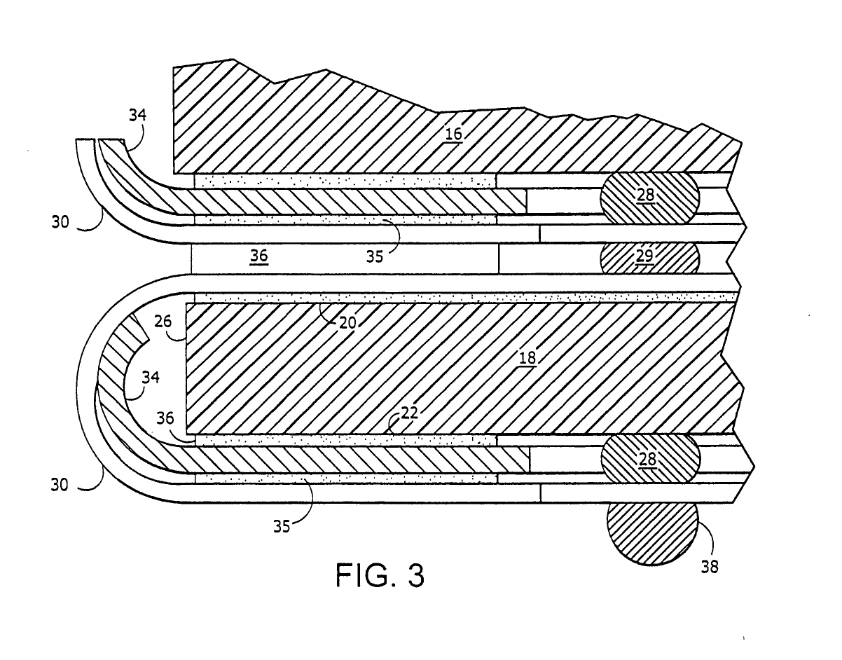

FIG. 3 is an enlarged depiction of the area marked “A” in FIG. 2. The connection strategy employed in module 10 as depicted in FIG. 2 and shown in greater detail in FIG. 3, includes a connective element 29 which, in a preferred embodiment, is a low profile contact formed from reflowed solder paste. The depiction of FIG. 3 is not to scale and typically, connective element 29 will exhibit less height than contact 28 in a preferred embodiment. When module 10 includes more than two CSPs, use of connective elements 29 to connect the flex circuitry at one level to the flex circuitry at a next level is preferred. Where a two-CSP module 10 is devised, the upper CSP 16 will not, in a preferred embodiment, have flex circuitry about it and, consequently, will not, in preferred embodiments, employ connective elements 29. In a two-CSP module 10, contacts 28 of upper CSP 16 directly contact the flex circuitry that is associated with lower CSP 18. Form standard 34 may be fixed to the lower (or upper) surface of the respective CSP with an adhesive 36 which preferably is thermally conductive.

Form standard 34 is, in a preferred embodiment, devised from nickel-plated copper to create a mandrel that mitigates thermal accumulation while providing a standard sized form about which flex circuitry is disposed. Form standard 34 may take other shapes and forms that are coincident with the respective CSP body. It also need not be thermally enhancing although such attributes are preferable. The form standard 34 allows the invention to be employed with CSPs of varying sizes, while articulating a single set of connective structures useable with the varying sizes of CSPs. Thus, a single set of connective structures such as flex circuits 30 and 32 (or a single flexible circuit in the mode where a single flex is used in place of the flex circuit pair 30 and 32) may be devised and used with the form standard 34 method and/or systems disclosed herein to create stacked modules with CSPs having different-sized packages. This will allow the same flex circuitry design to be employed to create iterations of a stacked module 10 from constituent CSPs having a first arbitrary dimension X across attribute Y (where Y may be, for example, package width), as well as modules 10 from constituent CSPs having a second arbitrary dimension X prime across that same attribute Y. Thus, CSPs of different sizes may be stacked into modules 10 with the same set of connective structures (i.e. flex circuitry). Further, as those of skill will recognize, mixed sizes of CSPs may be implemented into the same module 10.

In a preferred embodiment, portions of flex circuits 30 and 32 may be attached to form standard 34 by attachments 35 which, in a preferred embodiment, are metallic bonds. Preferred examples of such metallic bonding of flex circuitry to a form standard are further described in co-pending U.S. patent application Ser. No. 10/828,495, filed Apr. 20, 2004, which is commonly owned by the assignee of the present invention and hereby incorporated by reference. Other methods for attaching form standard 34 to flex circuitry may be employed in the present invention including, for example, a tape or liquid adhesive. If an adhesive is used for the attachment 35, the adhesive will be thermally conductive.

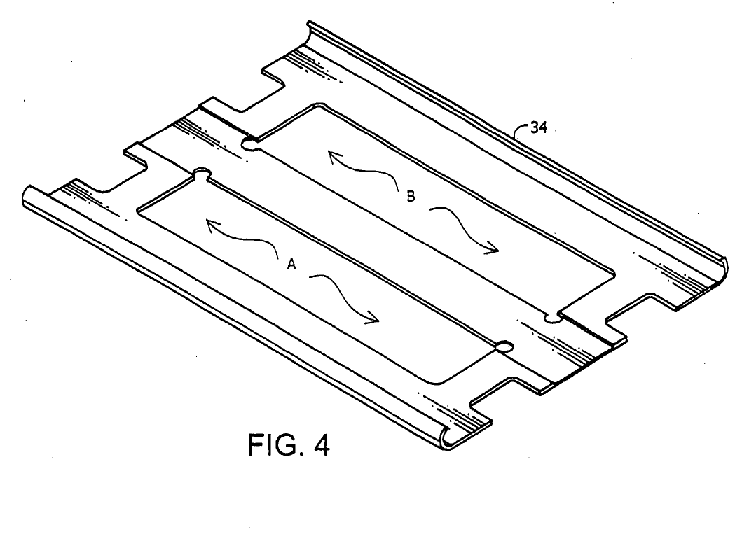

FIG. 4 illustrates an exemplar form standard 34 that may be employed in some preferred embodiments of the present invention. Form standard 34 as depicted in the preferred embodiment of FIG. 4 is comprised of nickel-plated cooper and exhibits two windows identified by references A and B to allow the array of contacts 28 that rise above lower surface 22 of the respective CSP to readily pass through form standard 34. Form standard 34 may take other configurations and may, for example, be devised in more than one piece.

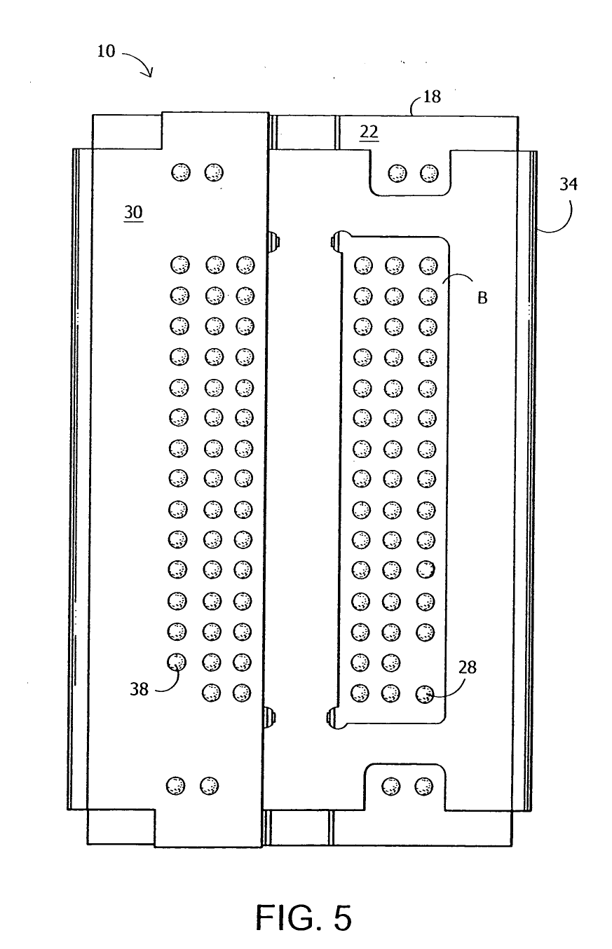

FIG. 5 is a plan view of an exemplar module 10 from below depicting an exemplar module 10 in which flex circuit 32 has been deleted to allow a view of the relationship between form standard 34 passing along lower planar surface 22 of CSP 18 and the flex circuitry employed in the module. On the right-hand side of the view of FIG. 5, and visible through window B of form standard 34, contacts 28 are shown rising from lower surface 22 of CSP 18 and projecting into window B. On the left-hand side of the view of FIG. 5, flex circuit 30 is represented as being disposed over part of form standard 34 and substantially all of window A of form standard 34. Module contacts 38 are shown along flex circuit 30.

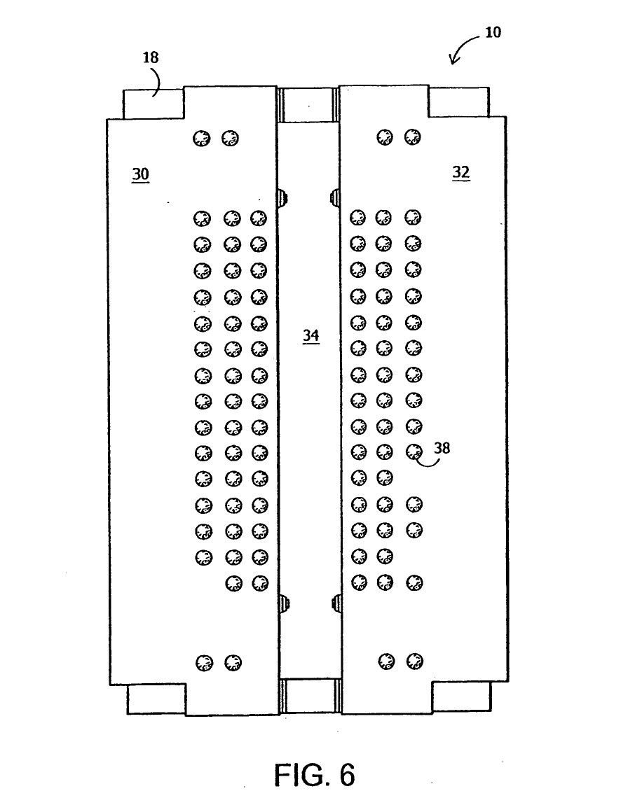

FIG. 6 is a plan view of a preferred embodiment of module 10.

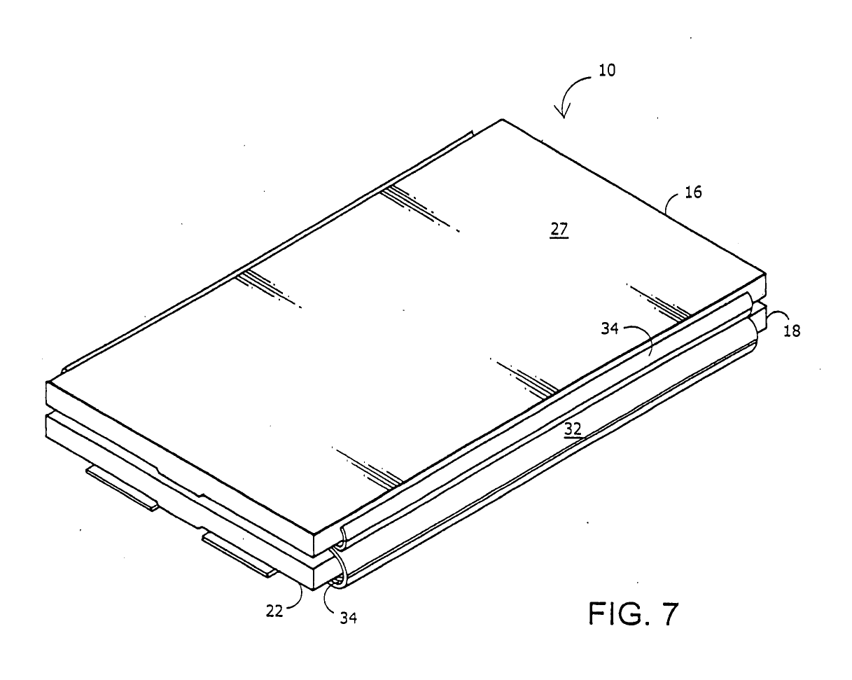

FIG. 7 is a perspective view of a module 10 devised in accordance with a preferred embodiment of the present invention. Form standard 34 is shown emerging beyond the perimeter of the body 27 of upper CSP 16 and opening upward relative to lower surface 22 of CSP 16. However, those of skill will appreciate that form standards in accordance with the present invention need not have an opening “direction” and may exhibit any sort of form about which the flex circuitry associated with that level in module 10 is extended to create the standard-sized template for the flex circuitry. On the first level of module 10 in FIG. 7, flex circuit 32 is visible while the form standard 34 associated with lower CSP 18 is just visible in the arc of flex circuit 32.

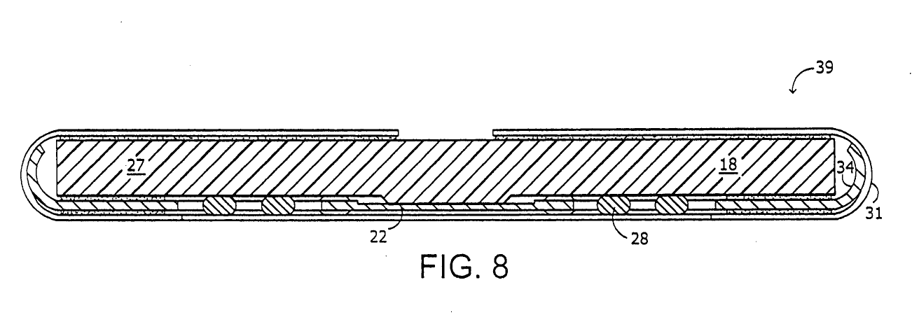

FIG. 8 depicts unit 39 devised in accordance with a preferred embodiment of the present invention. As those of skill will note, the flex circuitry employed in exemplar unit 39 is a single flex circuit 31 but as depicted in other embodiments, multiple flex circuits may also provide the flex circuitry employed in preferred embodiments of the invention. Multiple iterations of unit 39 may be stacked, preferably with earlier-described connectives 29 realizing the connection between constituent levels, to create a multi-level module 10 or, when combined with an upper CSP 16, a two-level module 10.

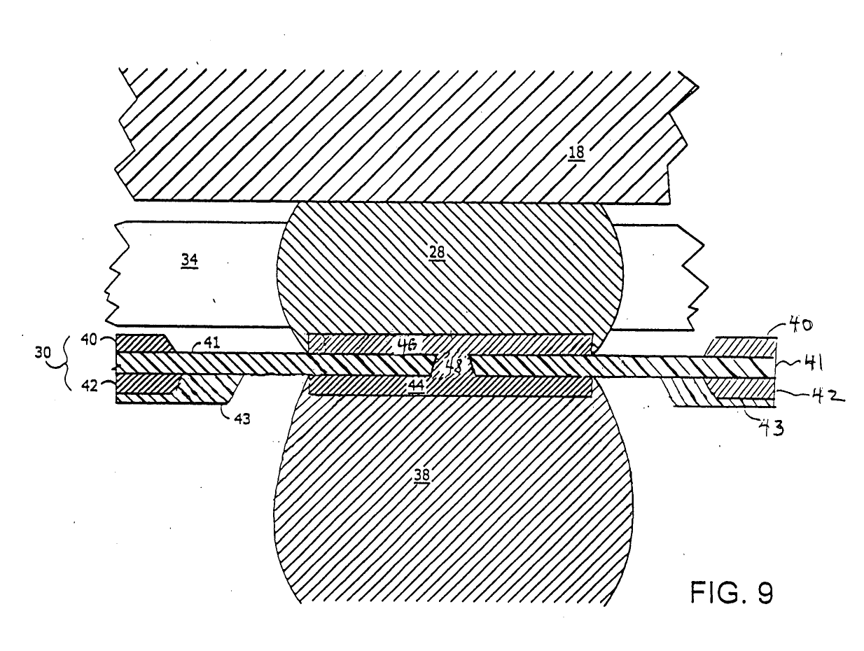

FIG. 9 is a cross-sectional view of a portion of a preferred embodiment taken through a window of form standard 34 depicting a preferred construction for flex circuitry which, in the depicted embodiment, is in particular, flex circuit 30 which comprises two conductive layers 40 and 42 separated by intermediate layer 41. Preferably, the conductive layers are metal such as alloy 110.

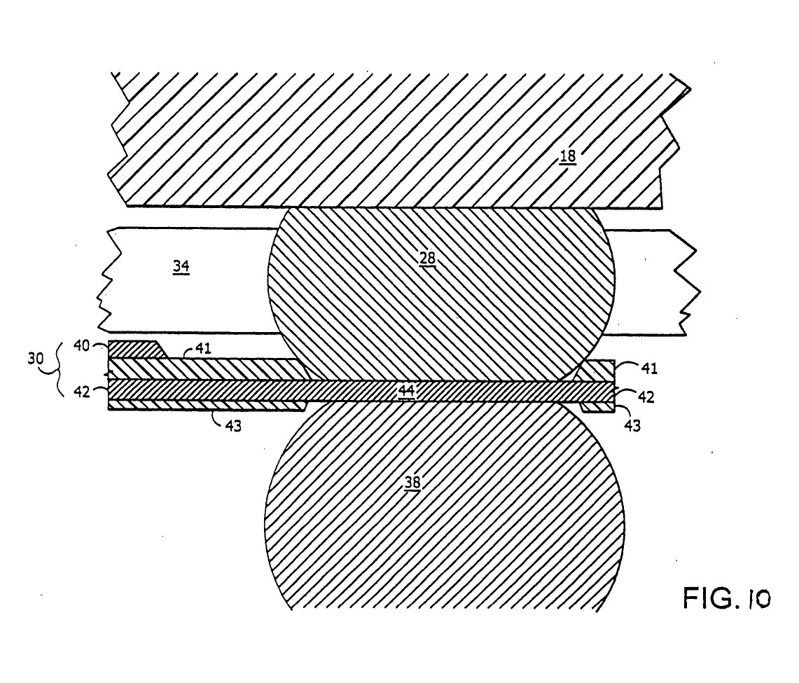

With continuing reference to FIG. 9, optional outer layer 43 is shown over conductive layer 42 and, as those of skill will recognize, other additional layers may be included in flex circuitry employed in the invention. Flex circuits that employ only a single conductive layer such as for example, those that employ only a layer such as conductive layer 42 may be readily employed in embodiments of the invention. The use of plural conductive layers provides, however, advantages and the creation of a distributed capacitance across module 10 intended to reduce noise or bounce effects that can, particularly at higher frequencies, degrade signal integrity, as those of skill in the art will recognize. In the depicted preferred embodiment, flex contact 44 at the level of conductive layer 42 and flex contact 46 at the level of conductive layer 40 provide contact sites to allow connection of module contact 38 and CSP contact 28 through via 48. Form standard 34 is seen in the depiction of FIG. 9 as contact 28 is within an opening of form standard 34 which, consequently, is not seen passing in front of contact 28 in the provided cross-sectional view. FIG. 10 depicts a cross-sectional view of an alternative preferred construction in a contact area in a module 10 devised in accordance with a preferred embodiment of the invention.

Although the present invention has been described in detail, it will be apparent to those skilled in the art that the invention may be embodied in a variety of specific forms and that various changes, substitutions and alterations can be made without departing from the spirit and scope of the invention. The described embodiments are only illustrative and not restrictive and the scope of the invention is, therefore, indicated by the following claims.

1. A high-density circuit module comprising:
a first CSP having first and second lateral sides and upper and lower major surfaces with CSP contacts along the lower major surface;
a second CSP having first and second lateral sides and upper and lower major surfaces with CSP contacts along the lower major surface and the second CSP being in stacked disposition above the first CSP;
a form standard disposed along and extending beyond the lower major surface of the first CSP.

2. The high-density circuit module of claim 1 in which the form standard exhibits an opening.

3. The high-density circuit module of claim 1 in which the form standard does not extend above a plane defined by the upper major surface of the first CSP.

4. The high-density circuit module of claim 2 in which the CSP contacts along the lower major surface of the first CSP project into the opening of the form standard.

5. The high-density circuit module of claim 1 in which the form standard exhibits at least two openings.

6. The high-density circuit module of claim 1 in which the form standard is attached to the first CSP with adhesive.

7. The high-density circuit module of claim 1 further comprising flex circuitry employed to connect the first and second CSPs.

8. The high-density circuit module of claim 7 in which the flex circuitry comprises first and second flex circuits.

9. The high-density circuit module of claim 7 in which the flex circuitry is disposed, in part, beneath the first CSP and, in part, above the first CSP.

10. The high-density circuit module of claim 9 in which the flex circuitry is attached to the form standard with metallic bonds.

11. The high-density circuit module of claim 7 in which the flex circuitry comprises at least two conductive layers.

12. The high-density circuit module of claim 7 in which the flex circuitry comprises two flex circuits and each of said flex circuits comprises at least two conductive layers.

13. The high-density circuit module of claim 1 further comprising a second form standard disposed along and extending beyond the lower major surface of the second CSP and flex circuitry employed to connect the first and second CSPs.

14. A high-density circuit module comprising:
a first CSP having first and second lateral sides and upper and lower major surfaces with CSP contacts along the lower major surface;
a second CSP having first and second lateral sides and upper and lower major surfaces with CSP contacts along the lower major surface and the second CSP being in stacked disposition above the first CSP;
a first form standard disposed along and extending beyond the lower major surface of the first CSP;
a second form standard disposed along and extending beyond the lower major surface of the second CSP; and
flex circuitry disposed, in part, beneath the first CSP and, in part, above the first CSP.

15. The high-density circuit module of claim 14 further comprising:
a third CSP having first and second lateral sides and upper and lower major surfaces with CSP contacts along the lower major surface;
a fourth CSP having first and second lateral sides and upper and lower major surfaces with CSP contacts along the lower major surface and the second CSP being in stacked disposition above the first CSP; and
a third form standard disposed along and extending beyond the lower major surface of the third CSP.

16. The high-density circuit module of claim 15 further comprising:
a fourth form standard disposed along and extending beyond the lower major surface of the fourth CSP.

17. The high-density circuit module of claim 14 in which the flex circuitry is comprised of two conductive layers.

18. The high-density circuit module of claim 14 in which the first form standard does not extend above a plane defined by the upper major surface of the first CSP.

19. The high density circuit module of claim 14 in which the first form standard does not extend above a plane defined by the upper major surface of the first CSP and the second form standard does not extend above a plane defined by the upper major surface of the second CSP.

20. A unit for use in aggregating CSPs, the unit comprising:
a CSP, having upper and lower major surfaces;
a form standard disposed along and extending beyond the lower major surface; and
flex circuitry attached to the form standard.
